(19) United States
(12) Patent Application Publication
(10) Pub. No.: US 2026/0188376 A1
(43) Pub. Date: Jul. 2, 2026

(54) SUB-CHANNEL SUPPORT ACROSS SAME MEMORY MODULE

(71) Applicant: Advanced Micro Devices, Inc., Santa Clara, CA (US)

(72) Inventors: Kedarnath Balakrishnan, Bangalore (IN); Jean J. Chittilappilly, Maynard, MA (US); Jing Wang, Austin, TX (US)

(73) Assignee: Advanced Micro Devices, Inc., Santa Clara, CA (US)

(21) Appl. No.: 19/004,829

(22) Filed: Dec. 30, 2024

(51) Int. Cl. G11C 11/406; G11C 11/4096

(52) U.S. Cl. CPC G11C 11/40603; G11C 11/40615; G11C 11/4096

(57) ABSTRACT

A memory controller system comprises a first memory controller for accessing a first sub-channel of a memory module, and a second memory controller for accessing a second sub-channel of the memory module. Each of the first and second memory controllers is configurable as one of a master memory controller and a slave memory controller. The master memory controller is enabled to send a global command to the memory module in response to a request, and the slave memory controller is disabled from sending the global command to the memory module in response to the request.

### BACKGROUND

Dynamic random-access memory (DRAM) chips include large arrays of memory cells which represent data as charges stored in capacitors. Most DRAM chips sold today are compatible with various double data rate (DDR) DRAM standards promulgated by the Joint Electron Devices Engineering Council (JEDEC). In many high-performance data processing systems, DDR memory chips are combined on a module with its own circuit board to allow wide bus widths and to allow the easy addition of memory to the system. One popular memory module form factor is known as a dual-inline memory module (DIMM). In one architecture, a DIMM uses a register clock driver (RCD) chip to buffer signals and to set global configuration parameters for the DIMM. Recently, DDR, version five (DDR5) memories have been introduced that support two independent sub-channels. However, it has been difficult to design memory controllers for the two sub-channels for operation with registered DIMMs that coordinate sending configuration commands to the RCD chip and refresh commands between memory controllers for the sub-channels without significant re-design.

### BRIEF DESCRIPTION OF THE DRAWINGS

FIG. 1 illustrates in block diagram form a data processing system according to some implementations;

FIG. 2 illustrates in block diagram form a data processing system having a dual-channel memory controller system according to some implementations;

FIG. 3 illustrates in block diagram form a memory controller suitable for use as one of the memory controllers in the data processing system of FIG. 2 according to some implementations;

FIG. 4 illustrates a first flow chart of a method for the dual-channel memory controller system of FIG. 2 according to some implementations;

FIG. 5 illustrates a second flow chart of a method for the dual-channel memory controller system of FIG. 2 according to some implementations; and

FIG. 6 illustrates a third flow chart of a method for the dual-channel memory controller system of FIG. 2 according to some implementations.

In the following description, the use of the same reference numerals in different drawings indicates similar or identical items. Unless otherwise noted, the word “coupled” and its associated verb forms include both direct connection and indirect electrical connection by means known in the art, and unless otherwise noted any description of direct connection implies alternate implementations using suitable forms of indirect electrical connection as well. The following Detailed Description is directed to electronic circuitry, and the description of a block shown in a drawing figure implies the implementation of the described function using suitable electronic circuitry, unless otherwise noted.

### DETAILED DESCRIPTION OF ILLUSTRATIVE IMPLEMENTATIONS

The inventors have developed a memory controller, system, and method that is modular but also supports coordination between memory controllers for two different sub-channels without costly re-design. Two generic memory controllers are configured as either a master memory controller or a slave memory controller, in which the master memory controller is enabled to send commands to a register clock driver (RCD) chip, while the slave memory controller is disabled from sending commands to the RCD chip. Providing the generic memory controller design allows the independent scheduling of commands to two independent sub-channels, while allowing only the master memory controller to program common settings into the RCD. For example, these memory controllers are each capable of addressing different sub-channels of a graphics double data rate version 5 (GDDR5) memory module that supports two independently addressable sub-channels to increase system performance without requiring a costly re-design of the memory controller. In addition, these memory controllers operate according to a token-based, peer-to-peer protocol to coordinate the scheduling of refresh commands to their respective sub-channels.

A memory controller system includes a first memory controller for accessing a first sub-channel of a memory module, and a second memory controller for accessing a second sub-channel of the memory module. Each of the first and second memory controllers is configurable as one of a master memory controller and a slave memory controller. The master memory controller is enabled to send a global command to the memory module in response to a request, and the slave memory controller is disabled from sending the global command to the memory module in response to the request.

A memory controller includes a register for receiving and storing a master/slave signal and a control circuit. The control circuit is operative to enable the memory controller to send a global command to a memory interface to program a register clock driver of a memory module if the master/slave signal indicates the memory controller is a master memory controller. The control circuit is operative to prevent the memory controller from sending the global command to the memory interface to program the register clock driver of the memory module if the master/slave signal indicates the memory controller is a slave memory controller.

A method for accessing two channels of a memory module using first and second memory controllers, respectively, includes configuring one of the first memory controller and the second memory controller as a master memory controller, and configuring another one of the first memory controller and the second memory controller as a slave memory controller. A request to change a state of the memory module is received. The master memory controller is enabled to send a command in response to the request. The slave memory controller is prevented from sending the command in response to the request.

A memory controller system, memory controller, and method as described herein allow a single, universal memory controller to be configured as either a master memory controller or a slave memory controller. The master memory controller is enabled to send global commands to, e.g., a register clock driver (RCD) chip of a DIMM, while the slave memory controller is disabled from sending global commands to the RCD chip. Two examples of such commands are configuration commands and error processing for imprecise errors. In addition, the memory controllers, so configured, operate using a token-based, peer-to-peer protocol to coordinate sending refreshes so that refreshes for each of the two sub-channels are scheduled evenly over the refresh interval.

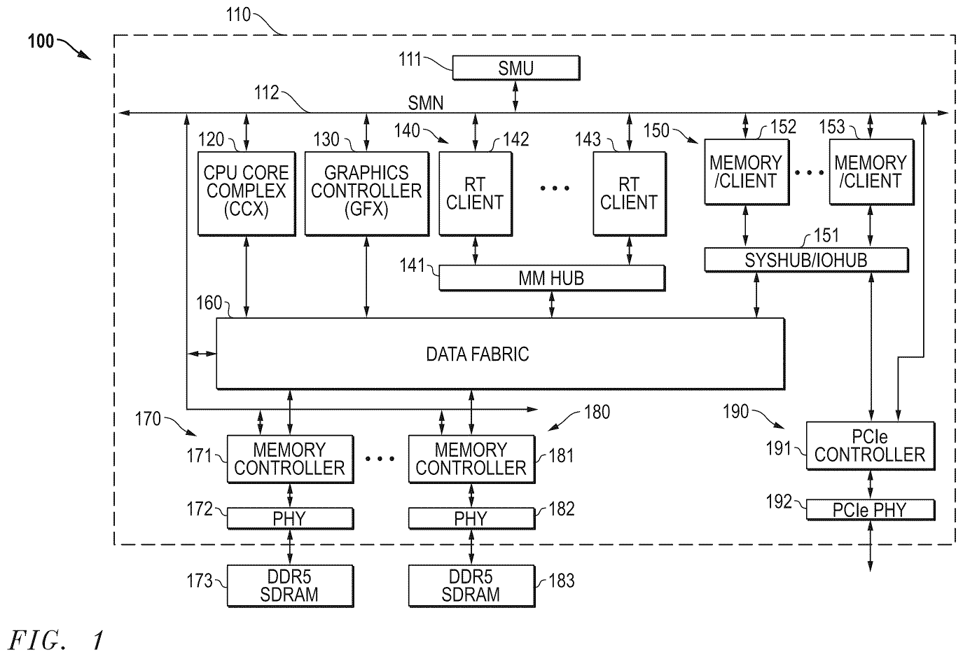

FIG. 1 illustrates in block diagram form a data processing system 100 according to some implementations. Data processing system 100 includes a data processor 110 in the form of an accelerated processing unit (APU) and memory in the form of double data rate version 5, synchronous dynamic random-access memory (DDR5 SDRAMs) including a DDR5 memory 173 and a DDR5 memory 183. Many other components of an actual data processing system are typically present but are not relevant to understanding the present disclosure and are not shown in FIG. 1 for ease of illustration.

Data processor 110 includes generally a system management unit 111 labelled “SMU”, a system management network (SMN) 112, a central processing unit (CPU) core complex 120 labeled “CCX”, a graphics controller 130 labeled “GFX”, a real-time client subsystem 140, a memory/client subsystem 150, a data fabric 160, memory channels 170 and 180, and a Peripheral Component Interface Express (PCIe) subsystem 190. As will be appreciated by a person of ordinary skill, data processor 110 may not have all of these elements present in every implementation and, further, may have additional elements included therein.

SMU 111 is bidirectionally connected to the major components in data processor 110 over SMN 112. SMN 112 forms a control fabric for data processor 110. SMU 111 is a local controller that controls the operation of the resources on data processor 110 and synchronizes communication among them. SMU 111 manages power-up sequencing of the various processors on data processor 110 and controls multiple off-chip devices via reset, enable and other signals. SMU 111 includes one or more clock sources (not shown), such as a phase locked loop (PLL), to provide clock signals for each of the components of data processor 110. SMU 111 also manages power for the various processors and other functional blocks, and may receive measured power consumption values from CPU cores in CPU core complex 120 and graphics controller 130 to determine appropriate P-states.

CPU core complex 120 includes a set of CPU cores, each of which is bidirectionally connected to SMU 111 over SMN 112. Each CPU core may be a unitary core only sharing a last-level cache with the other CPU cores, or may be combined with some but not all of the other cores in clusters.

Graphics controller 130 is bidirectionally connected to SMU 111 over SMN 112. Graphics controller 130 is a high-performance graphics processing unit (GPU) capable of performing graphics operations such as vertex processing, fragment processing, shading, texture blending, and the like in a highly integrated and parallel fashion. In order to perform its operations, graphics controller 130 requires periodic access to external memory. In the implementation shown in FIG. 1, graphics controller 130 shares a common memory subsystem with CPU cores in CPU core complex 120, an architecture known as a unified memory architecture. Because data processor 110 includes both a CPU and a GPU, it is also referred to as an APU.

Real-time client subsystem 140 includes a set of real-time clients such as representative real time clients 142 and 143, and a memory management hub 141 labeled “MM HUB”. Each real-time client is bidirectionally connected to SMU 111 over SMN 112, and to memory management hub 141. Real-time clients in real-time client subsystem 140 could be any type of peripheral controller that requires periodic movement of data, such as an image signal processor (ISP), an audio coder-decoder (codec), a display controller that renders and rasterizes objects generated by graphics controller 130 for display on a monitor, and the like.

Memory/client subsystem 150 includes a set of memory elements or peripheral controllers such as representative memory/client devices 152 and 153, and a system and input/output hub 151 labeled “SYSHUB/IOHUB”. Each memory/client device is bidirectionally connected to SMU 111 over SMN 112, and to system and input/output hub 151. Memory/client devices are circuits that either store data or require access to data on an aperiodic fashion, such as a non-volatile memory, a static random-access memory (SRAM), an external disk controller such as a Serial Advanced Technology Attachment (SATA) interface controller, a universal serial bus (USB) controller, a system management hub, and the like.

Data fabric 160 is an interconnect that controls the flow of traffic in data processor 110. Data fabric 160 is bidirectionally connected to SMU 111 over SMN 112, and is bidirectionally connected to CPU core complex 120, graphics controller 130, memory management hub 141, system and input/output hub 151. Data fabric 160 includes a crossbar switch for routing memory-mapped access requests and responses between any of the various devices of data processor 110. It includes a system memory map, defined by a basic input/output system (BIOS), for determining destinations of memory accesses based on the system configuration, as well as buffers for each virtual connection.

Memory channels 170 and 180 are circuits that control the transfer of data to and from DDR5 memory 173 and DDR5 memory 183. Memory channel 170 is formed by a memory controller 171 and a physical interface circuit 172 labeled “PHY” connected to DDR5 memory 173. Memory controller 171 is bidirectionally connected to SMU 111 over SMN 112 and has an upstream port bidirectionally connected to data fabric 160, and a downstream port. Physical interface circuit 172 has an upstream port bidirectionally connected to memory controller 171, and a downstream port bidirectionally connected to DDR5 memory 173. Similarly, memory channel 180 is formed by a memory controller 181 and a physical interface circuit 182 connected to DDR5 memory 183. Memory controller 181 is bidirectionally connected to SMU 111 over SMN 112 and has an upstream port bidirectionally connected to data fabric 160, and a downstream port. Physical interface circuit 182 has an upstream port bidirectionally connected to memory controller 181, and a downstream port bidirectionally connected to DDR5 memory 183.

Peripheral Component Interface Express (PCIe) subsystem 190 includes a PCIe controller 191 and a PCIe physical interface circuit 192. PCIe controller 191 is bidirectionally connected to SMU 111 over SMN 112 and has an upstream port bidirectionally connected to system and input/output hub 151, and a downstream port. PCIe physical interface circuit 192 has an upstream port bidirectionally connected to PCIe controller 191, and a downstream port bidirectionally connected to a PCIe fabric, not shown in FIG. 1. PCIe controller is capable of forming a PCIe root complex of a PCIe system for connection to a PCIe network including PCIe switches, routers, and devices.

In operation, data processor 110 integrates a complex assortment of computing and storage devices, including CPU core complex 120 and graphics controller 130, on a single chip. Most of the features of these controllers are well known and will not be discussed further. However, as will be described in greater detail below, a data processor includes a memory controller with a command queue for storing memory access requests and a refresh controller, connected to the command queue and operable to select an order of providing same bank refresh commands to a plurality of refresh groups of corresponding banks in the memory based on an aggregate request count of the memory access requests in the command queue. Specifically, during a round of same bank refreshes, the memory controller repeatedly picks refresh groups with the lowest aggregate request count among the refresh groups that have not yet been picked in the current round until all refresh groups have been picked. Thus, the memory controller ensures that all memory banks are refreshed with the refresh interval (tREFI), while intelligently selecting the order to improve bus utilization and reduce command latency.

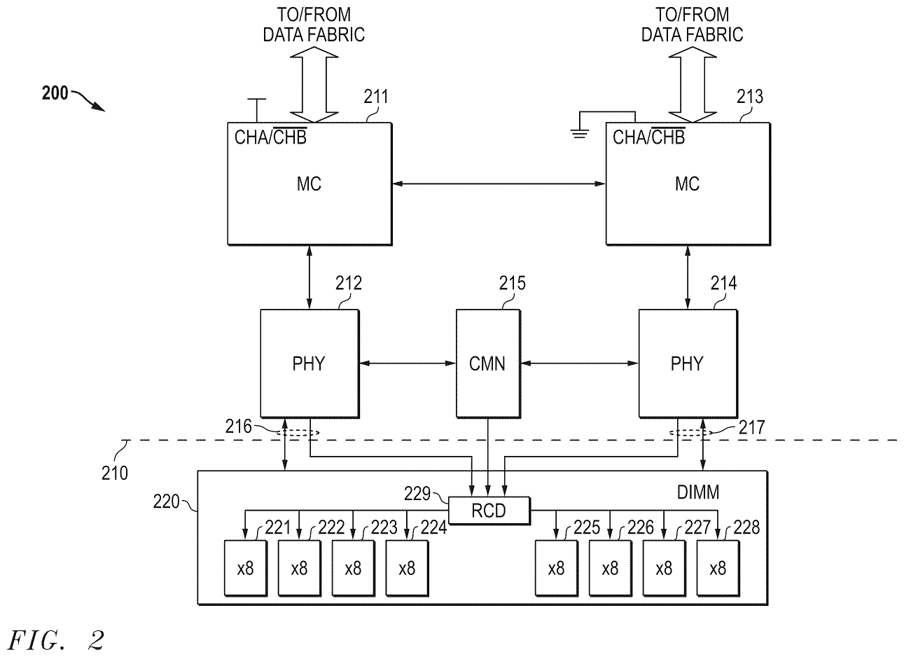

FIG. 2 illustrates in block diagram form a data processing system 200 having a dual-channel memory controller system according to some implementations. Data processing system 200 includes generally a data processor 210 and a memory module 220.

Data processor 210 includes a memory controller 211 and its corresponding physical interface circuit 212, and a memory controller 213 and its corresponding physical interface circuit 214, and a common circuit 215 labelled “CMN”. First memory controller 211 includes a configuration terminal labelled “CHA/CHB” connected to a more-positive power supply voltage terminal labelled “V_{DD}”, a bidirectional upstream port connected to data fabric 160, a bidirectional downstream port, and a bi-directional synchronization port. As used in this description, upstream is on a side toward the data processor cores (e.g., CPU core complex 120) and away from the memory system (e.g., memory module 220), and downstream is on a side toward the memory system and away from the data processor cores. PHY 212 has an upstream port connected to the downstream port of memory controller 211, a bidirectional downstream port, a bidirectional control port, and a downstream output port, in which the bidirectional downstream port and the downstream output port conduct command/address and data signals, respectively, of a sub-channel 216. Memory controller 213 includes a configuration terminal connected to a more-negative, ground power supply voltage terminal, a bidirectional upstream port connected to data fabric 160, a bidirectional downstream port, and a bi-directional synchronization port connected to the bidirectional synchronization port of memory controller 213. PHY 214 has an upstream port connected to the downstream port of memory controller 213, a bidirectional downstream port, a bidirectional control port, and a downstream output port, in which the bidirectional downstream port and the downstream output port conduct command/address and data signals, respectively, of a sub-channel 217. Common circuit 215 has a first bidirectional control port connected to the bidirectional control port of physical interface circuit 212, a second bidirectional control port connected to the bidirectional control port of physical interface circuit 214, and an output.

Memory module 220 includes a register clock driver 229 and a set of eight by-8 (×8) memory chips 221-228 mounted on a common printed circuit board substrate. Register control device 229 has inputs connected to the outputs of physical interface circuits 212 and 214 and to the output of common circuit 215, and outputs connected to each of memory chips 221-228. Memory module 220 is a dual-inline memory module (DIMM) capable of supporting memory devices on both the front side and the back side of the printed circuit board substrate. In the example shown in FIG. 2, memory module 220 is a DDR5 dual inline memory module, and supports two, independently addressable 32-bit sub-channels to increase overall performance.

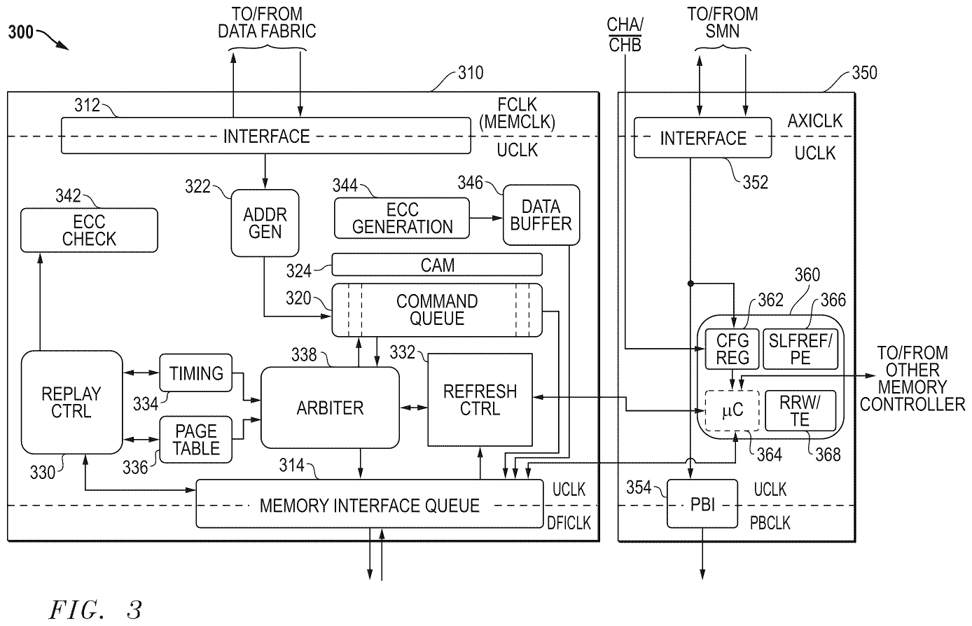

FIG. 3 illustrates in block diagram form a memory controller 300 suitable for use as one of the memory controllers in data processing system 200 of FIG. 2 according to some implementations. Memory controller 300 includes a memory channel controller 310 and a power controller 350. Memory channel controller 310 includes an interface 312, a memory interface queue 314, a command queue 320, an address generator 322, a content addressable memory 324 labelled “CAM”, a replay queue 330, a refresh controller 332, a timing block 334, a page table 336, an arbiter 338, an error correction code (ECC) check block 342, an ECC generation block 344, and a data buffer 346 labelled “DB”.

Interface 312 has a first bidirectional connection to data fabric 125 over an external bus, and has an output. Interface 312 translates memory access requests from a first clock domain known as the FCLK (or MEMCLK) domain to a second clock domain internal to memory controller 300 known as the UCLK domain. Similarly, memory interface queue 314 provides memory accesses from the UCLK domain to the DFICLK domain associated with the DDR-to-PHY (DFI) interface.

Address generator 322 decodes addresses of memory access requests received from data fabric 125. The memory access requests include access addresses in the physical address space represented in as a normalized address. Address generator 322 converts the normalized addresses into a format that can be used to address the actual memory devices in the memory system, as well as to efficiently schedule related accesses. This format includes a region identifier that associates the memory access request with a particular rank, a row address, a column address, a bank address, and a bank group. On startup, the BIOS queries the memory devices in the memory system to determine their size and configuration, and programs a set of configuration registers associated with address generator 322. Address generator 322 uses the configuration stored in the configuration registers to translate the normalized addresses into the appropriate format.

Command queue 320 is a queue of memory access requests received from the memory accessing agents in data processor 110, such as CPU core complex 120, graphics controller 130, etc. Command queue 320 stores the address fields decoded by address generator 322 as well other address information that allows arbiter 338 to select memory accesses efficiently, including access type and quality of service (QoS) identifiers. Content addressable memory 324 includes information to enforce ordering rules, such as write after write (WAW) and read after write (RAW) ordering rules.

Replay controller 330 includes a temporary queue for storing memory accesses picked by arbiter 338 that are awaiting responses, such as address and command parity responses, write cyclic redundancy check (CRC) responses for DDR4 DRAM, or write and read CRC responses for DDR5 and GDDR5 DRAM. Replay controller 330 accesses error correcting code check block 342 to determine whether the returned ECC is correct or indicates an error. Replay controller 330 allows the accesses to be replayed in the case of a parity or CRC error of one of these cycles.

Refresh controller 332 is a hardware circuit that includes various circuitry including timers, counters, state machines, registers, digital logic, and the like to implement same bank refresh commands, as well as various powerdown, refresh, and termination resistance (ZQ) calibration cycles that are generated separately from normal read and write memory access requests received from memory accessing agents. For example, if a memory rank is in precharge powerdown, it must be periodically awakened to run refresh cycles. In general, refresh controller 332 generates refresh commands periodically to prevent data errors caused by leaking of charge off storage capacitors of memory cells in DRAM chips. In addition, refresh controller 332 periodically calibrates ZQ to prevent mismatch in on-die termination resistance due to thermal changes in the system. Refresh controller 332 also decides when to put DRAM devices in different power down modes.

Arbiter 338 is bidirectionally connected to command queue 320 and is the heart of memory channel controller 310. It improves efficiency by intelligent scheduling of accesses to improve the usage of the memory bus. Arbiter 338 uses timing block 334 to enforce proper timing relationships by determining whether certain accesses in command queue 320 are eligible for issuance based on DRAM timing parameters. For example, each DRAM has a minimum specified time between activate commands to the same bank, known as “t_{RC}”. Timing block 334 maintains a set of counters that determine eligibility based on this and other timing parameters specified in the JEDEC specification, and is bidirectionally connected to replay controller 330. Page table 336 maintains state information about active pages in each bank and rank of the memory channel for arbiter 338, and is bidirectionally connected to replay controller 330.

In response to write memory access requests received from interface 312, ECC generation block 344 computes an ECC according to the write data. Data buffer 346 stores the write data and ECC for received memory access requests. It outputs the combined write data/ECC to memory interface queue 314 when arbiter 338 picks the corresponding write access for dispatch to the memory channel.

Power controller 350 includes an interface 352 to an advanced extensible interface, version one (AXI), a peripheral bus interface 354, and a power engine 360. Interface 352 has a first bidirectional connection to the SMN, which includes an input for receiving an event signal labeled “EVENT_n” shown separately in FIG. 3, and an output. Peripheral bus interface 354 has an input connected to the output of interface 352, and an output for connection to a PHY over the peripheral bus.

Power engine 360 has an input connected to the output of interface 352, and an output connected to an input of memory interface queue 314. Power engine 360 includes a set of configuration registers 362, a microcontroller (μC) 364, a self refresh controller 366 labelled “SLFREF/PE”, and a reliable read/write training engine 368 labelled “RRW/TE”. Configuration registers 362 are programmed over the system management network, and store configuration information to control the operation of various blocks in memory controller 300. Accordingly, configuration registers 362 have outputs connected to these blocks that are not shown in detail in FIG. 3. Configuration registers 362 also include an input labelled “CHA/CHB” and include a register that receives and stores a respective master/slave signal, i.e., the CHA/CHB signal that configures memory controller 300 as either a master memory controller (when the CHA/CHB signal is high) or as a slave memory controller (with the CHA/CHB signal is low). Microcontroller 364 is an implementation of a control circuit and has an input connected to configuration registers 362 for receiving configuration information, a bidirectional connection to another memory controller for sending acknowledgments in a manner that will be described more fully below, a bidirectional connection to refresh controller 332, and a bidirectional connection to peripheral bus interface 354. Microcontroller 364 is a control circuit operative to enable one of the first memory controller (e.g., memory controller 211) and second (e.g., memory controller 213) memory controllers to send a global command to a memory interface queue 314 to program register clock driver 229 of memory module 220 if the respective master/slave signal indicates a master (e.g., when the CHA/CHB signal is high), and to disable (i.e., prevent) the one of the first memory controller and second memory controller from sending the global command to memory interface queue 314 to program register clock driver 229 of memory module 220 if the respective master/slave signal indicates a slave (e.g., when the CHA/C̅H̅B̅ signal is high). Self refresh controller 366 is an engine that allows the manual generation of refreshes in addition to the automatic generation of refreshes by refresh controller 332. Reliable read/write training engine 368 provides a continuous memory access stream to memory or I/O devices for such purposes as DDR interface read latency training and loopback testing.

Memory channel controller 310 includes circuitry that allows it to pick memory accesses for dispatch to the associated memory channel. In order to make the desired arbitration decisions, address generator 322 decodes the address information into predecoded information including rank, row address, column address, bank address, and bank group in the memory system, and command queue 320 stores the predecoded information. Configuration registers 362 store configuration information to determine how address generator 322 decodes the received address information. Arbiter 338 uses the decoded address information, timing eligibility information indicated by timing block 334, and active page information indicated by page table 336 to efficiently schedule memory accesses while observing other criteria such as QoS requirements. For example, arbiter 338 implements a preference for accesses to open pages to avoid the overhead of precharge and activation commands required to change memory pages, and hides overhead accesses to one bank by interleaving them with read and write accesses to another bank. In particular during normal operation, arbiter 338 may decide to keep pages open in different banks until they are required to be precharged prior to selecting a different page.

Memory controller 300 is configured to operate as either a master memory controller when CHA/C̅H̅B̅ signal is high, or as a slave memory controller when CHA/C̅H̅B̅ signal is low. The CHA/C̅H̅B̅ signal can be set in a variety of ways, including tying an input to a logic state using a photomask option or a programmable fuse, programming a register at system boot, and the like. Each of memory controllers 211 and 213 are hardware circuits that have the same circuit design, but are configured such that one is the master memory controller and one is the slave memory controller. This technique allows the same circuit to be duplicated but to be configured differently.

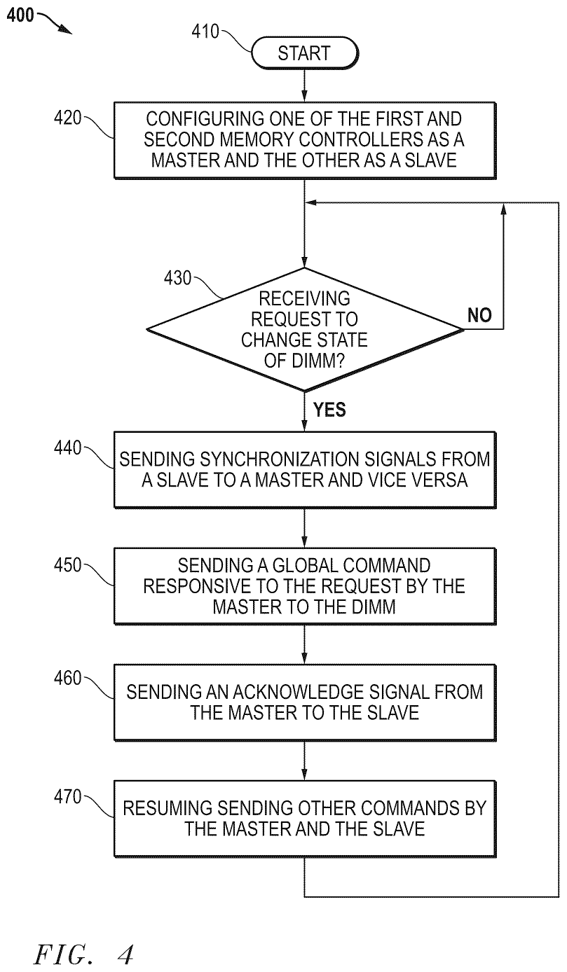

FIG. 4 illustrates a first flow chart of a method 400 for data processing system 200 of FIG. 2 according to some implementations. Method 400 starts in an action box 410.

An action box 420 includes configuring one of the first and second memory controllers as a master memory controller, and the other one as a slave memory controller. The master memory controller is a master in the sense that it has been enabled to send global commands to memory module 220 in response to a request on behalf of it and the slave memory controller, while the slave memory controller is a slave in the sense that it has been disabled from sending global commands in response to the request. In this way, the memory controller system for a dual-channel memory such as memory module 220 of FIG. 2 can be formed using two generic, programmable memory controllers, in which one is programmed as the “Channel A” or master memory controller, while the other is programmed as the “Channel B” or slave memory controller. Thus, one generic memory controller can be designed and verified, but configured for use as either a master or a slave.

A decision box 430 includes determining whether a request to change the state of the DIMM has been received. In one example, a change of state could be changing a configuration, such as enabling or disabling parity. Another change of state could be changing a power mode, such as placing the memory chips on the DIMM into a low-power self-refresh mode. It should be apparent that these are just examples of a variety of states of the DIMM to which method 400 would apply.

An action box 440 includes sending a synchronization signal from the slave to the master and from the master to the slave. The synchronization signals could be sent in any order, and in general, each memory controller could arrive at a synchronization point at different times. For example, each memory controller could arrive at a state in which it waits for synchronization from the other memory controller. When both master and slave memory controllers independently reach the state in which is waits for the synchronization signal from the other memory controller.

An action box 450 includes sending a global command responsive to the change of state request by the master memory controller to the DIMM. For the case of registered DIMMs like memory module 220 of FIG. 2, the global command could be a global control word (GCW) write to register clock driver 229 of a registered DIMM using DDR5 memory. It can also include other types of commands that are global in the sense that they affect both the master and the slave memory controllers.

An action box 460 includes sending an acknowledge signal from the master memory controller to the slave memory controller. The acknowledge signal indicates that the master has completed sending the global command, including any latency for the global command after being sent to the RCD on the DIMM by the master memory controller.

An action box 470 includes the master and the slave memory controllers resuming sending other commands to the memory. These other commands include commands such as normal reads and writes to memory, activate commands, precharge commands, and the like.

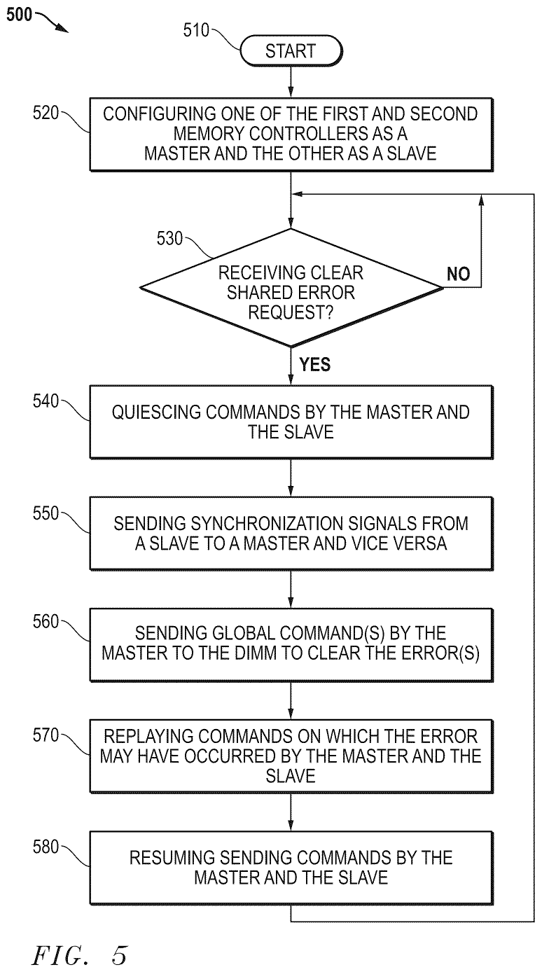

FIG. 5 illustrates a second flow chart of a method 500 for the dual-channel memory controller system 20 of FIG. 2 according to some implementations. Method 500 starts in an action box 510.

An action box 520 includes configuring one of the first and second memory controllers as a master memory controller, and configuring the other one of the first and second memory controllers as a slave memory controller. A memory controller system for a dual-channel memory such as memory module 220 of FIG. 2 can be formed using two generic, programmable memory controllers, in which one is programmed as the Channel A or master memory controller, while the other is programmed as the Channel B or slave memory controller. This system avoids the need to design separate master and slave memory controllers that must be verified separately.

A decision box 530 includes determining whether a request to change a state of a memory module whether a clear shared error request has been received. If not, the flow returns to decision box 530. If so, then flow continues to an action box 540. In the particular example of FIG. 5, the request to change the state includes a request to change a shared error state.

An action box 540 includes quiescing commands by the master memory controller and the slave memory controller. In some implementations, quiescing commands includes completing all outstanding memory access requests by sending completion responses to requestors. In other implementations, quiescing commands includes not only completing all outstanding memory access requests by sending completion responses to requestors, but also stopping accepting new commands from the data fabric and launching and completing memory access requests that are in the command queue at the time of receiving the request.

An action box 550 includes sending a synchronization signal from the slave to the master and from the master to the slave. The synchronization signals could be sent in any order, and in general, each memory controller could arrive at a synchronization point at different times. For example, each memory controller has different numbers of pending requests with different page states and so the amount of time it would take to quiesce the pending memory activity will in general be different.

An action box 560 includes sending one or more global commands from the master memory controller to the DIMM to clear the error or to clear multiple errors, respectively. There could be multiple errors, depending on which error recovery sequences are enabled. For example, error recovery sequences for both command/address parity errors and write cyclic redundancy check (CRC) errors may be enabled and detected. In the case of a command error, it is a command to clear the errors so the command or commands on which the error occurred can be replayed. Replay is advantageous in the case the conditions that caused the error were transitory.

Collectively, action boxes 540, 550, and 560 enable the master memory controller to send a command in response to the request, and to prevent the slave memory controller from sending the command in response to the request. Action boxes 540, 550, and 560 thereby coordinate a change of state of the DIMM between the memory controllers for the two sub-channels.

An action box 570 includes replaying the command or commands on which the error may have occurred by both the master memory controller and the slave memory controller. Because an ALERT-type error signal is not precise as to the command that caused the error, all memory controllers must back up and replay all commands on which the error may have occurred. For this purpose, memory controller 300 of FIG. 3 includes a replay controller 330 that maintains a queue for all the outstanding commands that have not yet completed successfully. As long as the queue is deep enough, it can store all commands on which the error may have occurred long enough so that the corresponding command can be determined to have executed error-free before being removed from the queue.

An action box 580 includes resuming sending commands by both the master memory controller and the slave memory controller. Flow then returns to decision box 530 for the next error. While method 400 and method 500 illustrate changing the state of the memory system using two memory controllers for two corresponding sub-channels using two particular examples, the extension of these techniques to other contexts using a master memory controller and a slave memory controller will be readily apparent to those of ordinary skill in the art.

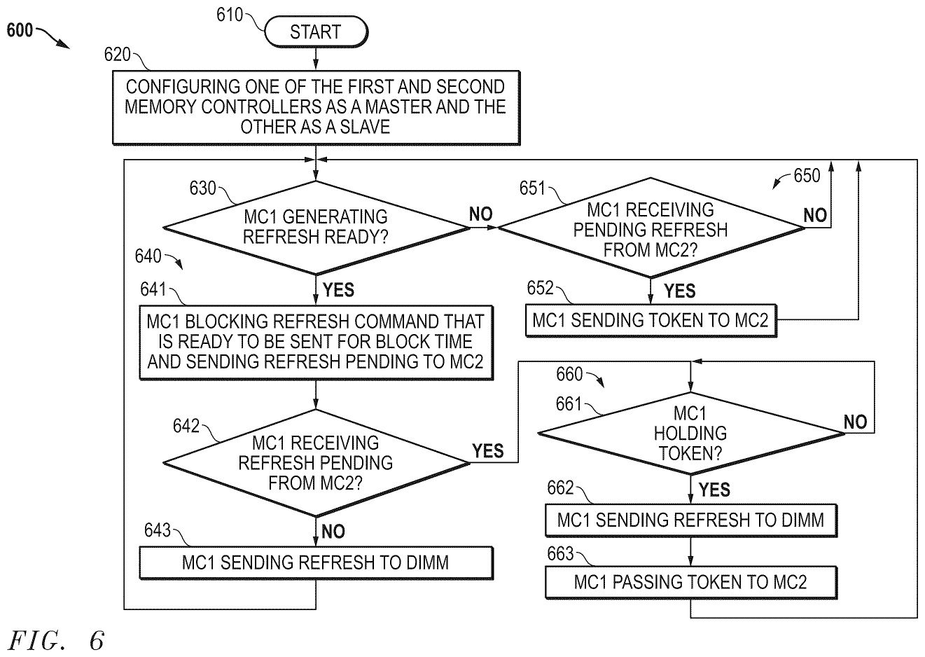

FIG. 6 illustrates a third flow chart of a method 600 for the dual-channel memory controller system of FIG. 2 according to some implementations. Method 600 relates to two memory controllers for each of the two sub-channels in which one memory controller is configured as a master memory controller and the other memory controller is configured as a slave memory controller. However, they operate as peer-to-peer entities for the purpose of issuing refresh commands to their respective sub-channels. Method 600 starts in an action box 610.

An action box 620 includes configuring one of the first and second memory controllers as a master memory controller, and configuring the other one of the first and second memory controllers as a slave memory controller. A memory controller system for a dual-channel memory such as memory module 220 of FIG. 2 can be formed using two generic, programmable memory controllers, in which one is programmed as the Channel A or master memory controller, while the other is programmed as the Channel B or slave memory controller. This system avoids the need to design separate master and slave memory controllers that must be verified separately.

Method 600 further describes the operation of a first memory controller designated as “MC1” in generating and completing refreshes. In a decision box 630, MC1 determines whether it has internally generated a refresh ready signal. As is well known, all memory cells in a DRAM must be refreshed, on average, within a refresh interval known as “tREFI”. Each memory controller has a refresh controller, e.g., refresh controller 332 of memory controller 300 FIG. 3, that generates periodic refresh ready signals to schedule refresh commands among other pending commands according to the capabilities of the memory controller. For example, DDR5 memory supports all-bank refresh commands, same-bank refresh commands, and fine granularity refresh commands, and the type of command used is selected according to the command latency needs of the system.

In response to MC1 generating a refresh ready signal, flow continues to a sub-flow 640. In sub-flow 640, an action box 641 includes MC1 blocking the refresh command that is otherwise ready to be sent for a block time that allows the other memory controller known as “MC2” to send its own refresh ready signal. A decision box 642 includes determining whether a refresh pending is received from MC2 during the blocking period. If not, flow continues to an action box 643, in which MC1 sends a refresh command to the DIMM, after which flow returns to decision box 630. If so, then flow continues to a sub-flow 660. In sub-flow 660, a decision box 661 determines whether MC1 is holding a token. The token is a state variable that MC1 coordinates with MC2 such that one and only one memory controller holds the token. As long as MC1 does not hold the token, then flow returns to decision box 661. When MC2 sends the token to MC1 after MC2 completes its refresh command, then flow proceeds to an action box 662 that includes MC1 sending the refresh command to the DIMM, followed by an action box 663 that includes MC1 passing the token to MC2. After passing the token to MC2, flow returns to decision box 630.

If the refresh controller in MC1 has not generated a refresh ready signal, then flow continues to a sub-flow 650. Sub-flow 650 includes a decision box 651, in which MC1 determines whether MC1 receives a pending refresh signal from MC2. If not, then flow returns to decision box 630. If so, then flow continues to an action box 652, which includes MC1 sending the token to MC2, and then flow returns to decision box 630.

Thus to perform the peer-to-peer sequence, in the example of refresh when the memory controller is ready to send a refresh command, the memory controller blocks sending commands for a period of time, outputs a refresh ready output signal, sends the refresh command to the memory module in response to not receiving a refresh ready input signal during the period of time, and sends the refresh command to the DIMM in response to receiving the refresh ready input signal during the period of time and the DIMM holding a token, and releases the token after sending the refresh command. This method implements a peer-to-peer protocol to implement refresh for the two sub-channels that in other respects operates using a master-slave protocol.

Thus, a universal memory controller, memory controller system, and method have been described that allow a single, universal memory controller to be configured as either a master memory controller or a slave memory controller. The master memory controller is enabled to send global commands to, e.g., a register clock driver (RCD) chip of a DIMM, while the slave memory controller is disabled from sending global commands to the RCD chip. Two examples of such commands are configuration commands and error processing commands for imprecise errors. In addition, the memory controllers, so configured, operate using a token-based, peer-to-peer protocol to coordinate sending refreshes so that refreshes for each of the two sub-channels are scheduled evenly over the refresh interval.

While particular implementations have been described, various modifications of these implementations will be apparent to those skilled in the art. For example, the memory controllers can be configured as a master memory controller or a slave memory controller in a variety of ways, including tying an input to a logic state using a photomask option, a programmable fuse, programming a register at system boot, and the like. While the master-slave coordination was described with respect to a global command and to clearing errors, other operations are possible. Moreover, while the particular memory supported two sub-channels, in the future, other numbers of sub-channels are possible. In these situations, a single memory controller would be configured as the master memory controller, while all remaining memory controllers would be configured as slave memory controllers. Also, use of this technique with other generations of memory or other types of memory besides DDR are also possible.

Accordingly, it is intended by the appended claims to cover all modifications of the disclosed implementations that fall within the scope of the disclosed implementations.

What is claimed is:

1. A memory controller system, comprising:
a first memory controller for accessing a first sub-channel of a memory module; and
a second memory controller for accessing a second sub-channel of the memory module,
wherein each of the first and second memory controllers is configurable as one of a master memory controller and a slave memory controller, wherein the master memory controller is enabled to send a global command to the memory module in response to a request, and the slave memory controller is disabled from sending the global command to the memory module in response to the request.

2. The memory controller system of claim 1, wherein:
the memory controller system causes a first one of the first and second memory controllers to operate as the master memory controller; and
the memory controller system causes a second one of the first and second memory controllers to operate as the slave memory controller.

3. The memory controller system of claim 2, wherein each of the first and second memory controllers comprises:
a register for receiving and storing a respective master/slave signal;
a control circuit operative to:
enable one of the first and second memory controllers to send the global command to a memory interface queue to program a register clock driver of the memory module if the respective master/slave signal indicates a master; and
disable the one of the first and second memory controllers from sending the global command to the memory interface queue to program the register clock driver (RCD) of the memory module if the respective master/slave signal indicates a slave.

4. The memory controller system of claim 2, wherein:
the slave memory controller sends a synchronization signal in response to receiving the request; and
the master memory controller waits to send a corresponding command to the memory module until it receives the synchronization signal from the slave memory controller.

5. The memory controller system of claim 4, wherein:
the master memory controller sends an acknowledgment signal to the slave memory controller in response to the master memory controller sending the corresponding command; and
the slave memory controller resumes sending other commands in response to the acknowledgment signal.

6. The memory controller system of claim 2, wherein in response to the memory controller system receiving the request:
both the master memory controller and the slave memory controller quiesce sending commands on a command and address bus; and
both the master memory controller and the slave memory controller send respective synchronization signals to each other.

7. The memory controller system of claim 6, wherein in response to both the master memory controller and the slave memory controller sending the respective synchronization signals to each other:
the master memory controller sends at least one command to the memory module to clear at least one corresponding error; and
both the master memory controller and the slave memory controller subsequently replay respective commands on which the at least one corresponding error may have occurred.

8. The memory controller system of claim 1, wherein when a first one of the first memory controller and the second memory controller is ready to send a refresh command, the first one of the first memory controller and the second memory controller:
blocks sending commands for a period of time;
sends a first pending refresh signal to a second one of the first and second memory controllers; and
sends the refresh command to the memory module in response to not receiving a refresh pending from the second one of the first and second memory controllers during the period of time.

9. The memory controller system of claim 8, wherein if the second one of the first and second memory controllers also provides a refresh pending signal:
the first one of the first memory controller and the second memory controller sends the refresh command in response to holding a token, and allocates the token to the second one of the first and second memory controllers after sending the refresh command.

10. A memory controller comprising:
a register for receiving and storing a master/slave signal;
a control circuit operative to:
enable the memory controller to send a global command to a memory interface queue to program a register clock driver of a memory module if the master/slave signal indicates the memory controller is a master memory controller; and
prevent the memory controller from sending the global command to the memory interface queue to program the register clock driver of the memory module if the master/slave signal indicates the memory controller is a slave memory controller.

11. The memory controller of claim 10, wherein:
the memory controller sends a synchronization signal without providing a corresponding command in response to receiving a request to program the register clock driver if the memory controller is the slave memory controller; and
the memory controller waits to send the corresponding command to the memory module until it receives the synchronization signal from the slave memory controller if the memory controller is the master memory controller.

12. The memory controller of claim 11, wherein:
the memory controller sends an acknowledgment signal in response to the sending the corresponding command if the memory controller is the master memory controller; and
the memory controller continues to send other commands in response to receiving the acknowledgment signal if the memory controller is the slave memory controller.

13. The memory controller of claim 10, wherein when the memory controller is ready to send a refresh command, the memory controller:
blocks sending commands for a period of time;
outputs a refresh ready output signal;
sends the refresh command to the memory module in response to not receiving a refresh ready input signal during the period of time; and
sends the refresh command to the memory module in response to receiving the refresh ready input signal during the period of time and the memory module holding a token, and releases the token after sending the refresh command.

14. A method for accessing two channels of a memory module using first and second memory controllers, respectively, comprising:
configuring a first one of the first memory controller and the second memory controller as a master memory controller;
configuring a second one of the first memory controller and the second memory controller as a slave memory controller;
receiving a request to change a state of the memory module;
enabling the master memory controller to send a command in response to the request; and
preventing the slave memory controller from sending the command in response to the request.

15. The method of claim 14, further comprising:
sending a first synchronization signal by the slave memory controller to the master memory controller;
sending a second synchronization signal from the master memory controller to the slave memory controller; and
sending the command to the memory module further in response to sending the first synchronization signal and the second synchronization signal.

16. The method of claim 15, further comprising:
sending an acknowledgment signal to the slave memory controller in response to the master memory controller sending a corresponding command; and
resuming sending other commands by the slave memory controller in response to the acknowledgment signal.

17. The method of claim 14, wherein in response to receiving a shared error signal:
quiescing sending commands on a command and address bus;
sending a first synchronization signal from the master memory controller to the slave memory controller; and
sending a second synchronization signal from the slave memory controller sends to the master memory controller.

18. The method of claim 17, wherein in response sending the first and second synchronization signals, respectively:
replaying master memory commands on which an error may have occurred;
replaying slave memory commands on which the error may have occurred; and
subsequently sending a command to the memory module to clear the error in response to a successful replay of the master memory commands and the slave memory commands.

19. The method of claim 14, wherein in response to a first one of the first memory controller and the second memory controller being ready to send a refresh command:
blocking sending commands for a period of time by the first one of the first memory controller and the second memory controller;
sending a first refresh ready signal to a second one of the first and second memory controllers; and
sending the refresh command to the memory module in response to not receiving a refresh ready from the second one of the first and second memory controllers during the period of time.

20. The method of claim 19, wherein if the second one of the first and second memory controllers also provides a refresh ready signal:
sending the refresh command by the first one of the first memory controller and the second memory controller in response to holding a token; and
allocating the token to the second one of the first and second memory controllers after sending the refresh command.
